(19) United States
(12) Patent Application Publication
(10) Pub. No.: US 2013/0341692 A1
(43) Pub. Date: Dec. 26, 2013

(54) Novel [N] Profile in Si-Ox Interface for CMOS Image Sensor Performance Improvement

(71) Applicants: Hsiao-Hui Tseng, Tainan City (TW); Jen-Cheng Liu, Hsin-Chu City (TW); Dun-Nian Yaung, Taipei City (TW); Tzu-Hsuan Hsu, Kaohsiung City (TW)

(72) Inventors: Hsiao-Hui Tseng, Tainan City (TW); Jen-Cheng Liu, Hsin-Chu City (TW); Dun-Nian Yaung, Taipei City (TW); Tzu-Hsuan Hsu, Kaohsiung City (TW)

(73) Assignee: TAIWAN SEMICONDUCTOR MANUFACTURING COMPANY, LTD., Hsin-Chu (TW)

(21) Appl. No.: 13/601,033

(22) Filed: Aug. 31, 2012

Related U.S. Application Data
(60) Provisional application No. 61/663,378, filed on Jun. 22, 2012.

(51) Int. Cl. H01L 27/146; H01L 21/8238

(52) U.S. Cl. 257/292; 438/218; 257/E27.13; 257/E21.632

(57) ABSTRACT

A semiconductor device including first and second isolation regions supported by a substrate, a first array well supported by the first isolation region, the first array well having a first field implant layer embedded therein, the first field implant layer surrounding a first shallow trench isolation region, a second array well supported by the second isolation region, the second array well supporting a doped region and a drain and having a second field implant layer embedded therein, the second field implant layer surrounding a second shallow trench isolation region, a stack of photodiodes disposed in the substrate between the first and second isolation regions, and a gate oxide formed over an uppermost photodiode of the stack of the photodiodes, the gate oxide and a silicon of the uppermost photodiode forming an interface, a nitrogen concentration at the interface offset from a peak nitrogen concentration.

### CROSS-REFERENCE TO RELATED APPLICATIONS

This application claims the benefit of U.S. Provisional Application No. 61/663,378, filed on Jun. 22, 2012, entitled “Novel [N] Profile in Si-Ox Interface for CMOS Image Sensor Performance Improvement,” which application is hereby incorporated herein by reference.

### BACKGROUND

A complementary metal-oxide-semiconductor (CMOS) image sensor (CIS) generally utilizes a series of photodiodes formed within an array of pixel regions of a semiconductor substrate in order to sense when light has impacted the photodiode. Adjacent to each of the photodiodes within each of the pixel regions, a transfer transistor may be formed in order to transfer the signal generated by the sensed light within the photodiode at a desired time. Such photodiodes and transfer transistors allow for an image to be captured at a desired time by operating the transfer transistor at the desired time.

The CIS may be formed in either a front side illumination (FSI) configuration or a back-side illumination (BSI) configuration. In a front-side illumination configuration, light passes to the photodiode from the “front” side of the image sensor where the transfer transistor has been formed. However, forcing the light to pass through any overlying metal layers, dielectric layers, and past the transfer transistor before it reaches the photodiode may generate processing and/or operational issues as the metal layers, dielectric layers, and the transfer transistor may not necessarily be translucent and easily allow the light to pass through.

In the BSI configuration, the transfer transistor, the metal layers, and the dielectric layers are formed on the front side of the substrate and light is allowed to pass to the photodiode from the “back” side of the substrate. As such, the light hits the photodiode before reaching the transfer transistor, the dielectric layers, or the metal layers. Such a configuration may reduce the complexity of the manufacturing of the image sensor and improve the image sensor operation.

The conventional CIS may be subject to an undesirable amount or level of random noise (RN) and dark currents (DC).

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 is perspective view of a representative portion of an embodiment complementary metal-oxide-semiconductor (CMOS) image sensor (CIS);

FIG. 2 is a cut-away portion of the CIS of FIG. 1 highlighting an interface between the gate oxide and the silicon of a photodiode in the CIS of FIG. 1;

FIG. 3 is a graph representing a nitrogen peak (i.e., [N] peak) relative to an interface between the oxide and the silicon of a photodiode in a conventional CIS; and

FIG. 4 is a graph representing a nitrogen peak (i.e., [N] peak) relative to an interface between the oxide and the silicon of a photodiode in the CIS of FIG. 1.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present disclosure provides many applicable inventive concepts that can be embodied in a wide variety of specific contexts. The specific embodiments discussed are merely illustrative and do not limit the scope of the disclosure.

The present disclosure will be described with respect to preferred embodiments in a specific context, namely a complementary metal-oxide-semiconductor (CMOS) image sensor (CIS). The concepts in the disclosure may also apply, however, to other semiconductor structures or circuits.

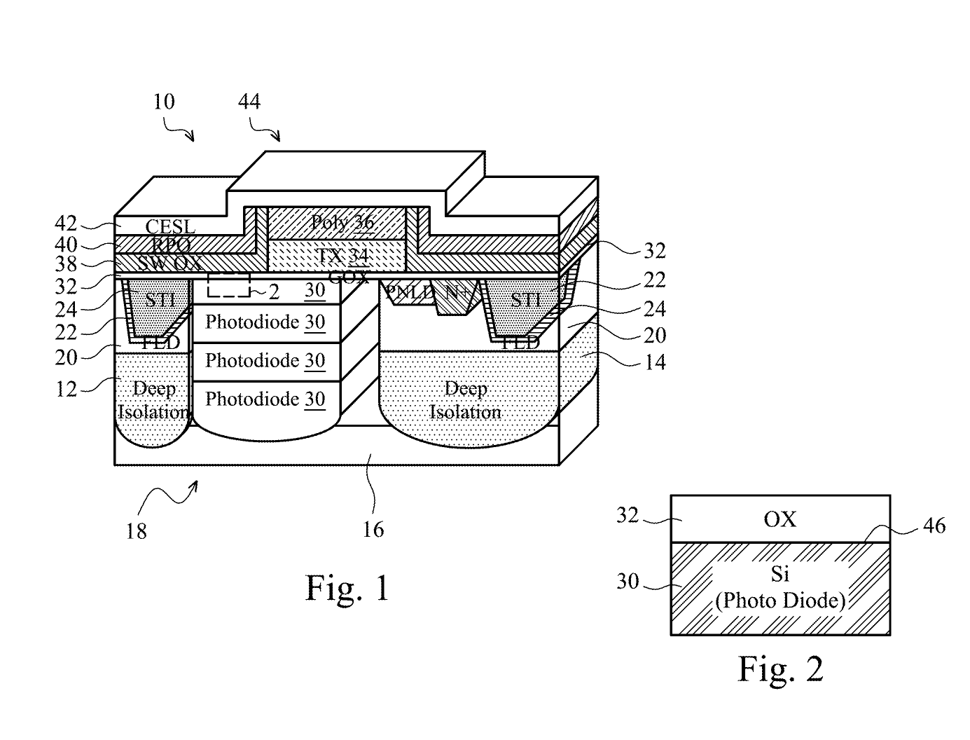

Referring to FIG. 1, an embodiment complementary metal-oxide-semiconductor (CMOS) image sensor (CIS) 10 is illustrated. As will be more fully explained below, the random noise (RN), the dark current (DC), and the leakage current are improved (i.e., reduced) in the CIS 10. In an embodiment, the CIS 10 includes first and second p-type isolation regions 12, 14 disposed in a p-type substrate 16. For the purposes of orientation, the substrate 16 in FIG. 1 is generally disposed at a front side 18 of the CIS 10. Each of the substrate 16 and first and second isolation regions 12, 14 may be formed from a suitable semiconductor material. The substrate 16 and the first and second isolation regions 12, 14 may be implanted with p-type impurities in the different doping concentrations.

As shown in FIG. 1, the first isolation region 12 supports an array p-well 20, which is a shallower isolation relative to the first and second isolation regions 12, 14. Embedded in the array p-well 20 is a p-type field implant layer 22 surrounding a shallow trench isolation (STI) region 24. The shallow trench isolation region 24 provides device isolation. The field implant layer 22 protects the underlying layers of the CIS 10 when the STI regions 24 are formed. In an embodiment, the STI region 24 and the field implant layer 22 are replaced by a region of impurities, which provides the device isolation.

The second isolation region 14 supports one of the filed implant layers 22 surrounding one of the shallow trench isolations (STI) regions 24. Unlike the first isolation region 12, the second isolation region 14 also supports a highly-doped n-type region 26 (i.e., an n+ region) and a pixel n-type lightly doped drain (PNLD) 28. As shown, the highly-doped n-type region 26 and the PNLD 28 are generally laterally adjacent to, and in contact with, each other.

Still referring to FIG. 1, several photodiodes 30 are disposed in the substrate 16 between the first and second isolations regions 12, 14. In an embodiment, four of the photodiodes 30 are vertically stacked and included in the CIS 10. It should be appreciated that more or fewer of the photodiodes 30 may be used in other embodiments.

In an embodiment, a gate oxide layer (GOX) 32 is formed over upwardly exposed portions of the array p-well 20, the field implant layer 22, the STI regions 24, and the uppermost photodiode 30. In an embodiment, the gate oxide layer 32 of FIG. 1 is formed by, for example, depositing or growing successive layers of oxide on previously deposited or grown oxide layers (e.g., grow layers of oxide twice to form a single composite gate oxide layer, grow layers of oxide three times, etc.). In addition, the parameters or characteristics of the oxide formation process may be precisely controlled by, for example, controlling a gas flow rate, controlling a process time, or manipulating the amount of an element used in the formation process (e.g., reducing the amount of nitrogen gas used in the process).

Still referring to FIG. 1, a transfer transistor (TX) 34 (a.k.a., transfer gate) is disposed over the gate oxide layer 32 in a central portion of the CIS 10. As shown, a portion of the transfer transistor 34 is disposed above the PNLD 28, which along with the highly-doped n+ region 26 functions as a drain for the transfer transistor 34.

As shown in FIG. 1, a layer of polysilicon 36 is disposed over the transfer transistor 34. In addition, a sidewall oxide layer (SW OX) 38 is formed over a portion of the gate oxide layer 32, sidewalls of the transfer transistor 34, and sidewalls of the polysilicon 36. Notably, in an embodiment the sidewall oxide layer 38 is not formed over a central portion of the gate oxide layer 32 disposed beneath the transfer transistor 34.

A layer of remote plasma oxide (RPO) 40 is formed over the external surfaces of the sidewall oxide layer 38. Still referring to FIG. 1, a contact etch stop layer (CESL) 42 is formed over the remote plasma oxide 40, the top surface of the vertically-oriented portion of sidewall oxide layer 38, and the polysilicon 36. For the purposes of orientation, the contact etch stop layer 42 in FIG. 1 is generally disposed at a back side 44 of the CIS 10. In other embodiments, other layers or materials may be included in the CIS 10.

Referring now to FIG. 2, a cut-away portion of the CIS 10 of FIG. 1 highlights an interface 46 between the silicon of the uppermost photodiode 30 and the oxide of the gate oxide layer 32. Through well control of the interface 46, the nitrogen and/or nitrogen concentration at the interface 46 can be beneficially manipulated. In an embodiment, well control of the interface 46 is performed by selecting one of the different methods of forming the gate oxide layer 32 (e.g., twice formed oxide, thrice formed oxide, etc.) and/or by controlling one or more parameters of the gate oxide layer 32 formation (e.g., gas flow rate, process time, concentration of nitrogen in gas, etc.).

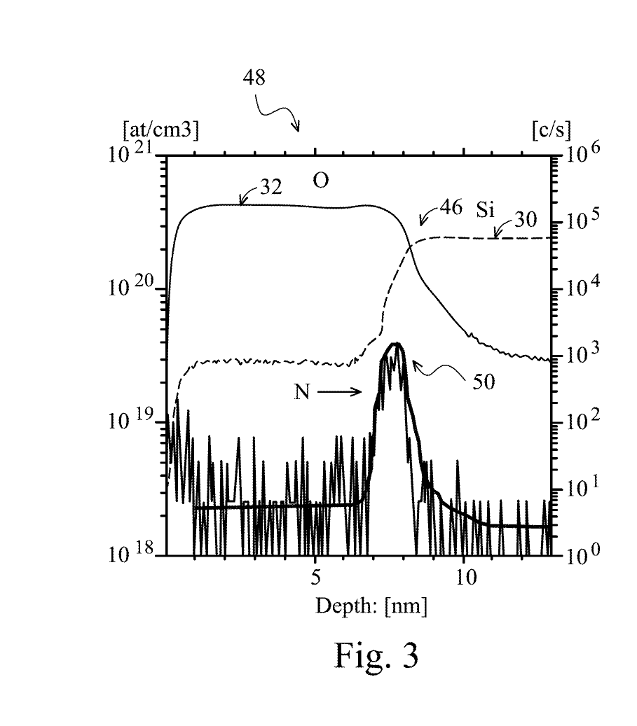

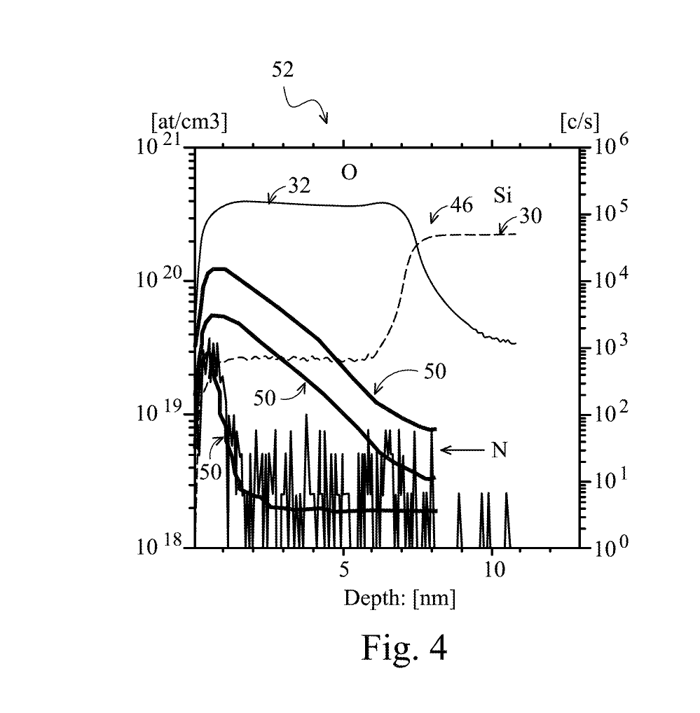

An illustrative example of how the nitrogen and/or nitrogen concentration at the interface 46 may be controlled is collectively depicted in FIGS. 3-4. Referring now to FIG. 3, a first graph 48 illustrates a typical nitrogen peak 50 (i.e., [N] peak) relative to the interface 46 of the oxide from the gate oxide layer 32 and the silicon of the photodiode 30 for a conventional CIS device. The nitrogen peak 50 may be determined using, for example, secondary ion mass spectrometry (SIMS) and creating a SIMS profile for the interface 46.

As shown in the first graph 48, the nitrogen peak 50 is almost directly below the interface 46, which leads to an undesirable amount of random noise, dark current, and/or leakage current in the conventional CIS device. In contrast, a second graph 52 of FIG. 4 illustrates several nitrogen peaks 50 relative to the interface 46 of the oxide from the gate oxide layer 32 and the silicon of the photodiode 30 from the CIS device 10 of FIG. 1. Notably, the nitrogen peaks 50 of FIG. 4 are each formed depending on which of the different process approaches is taken.

As shown in the second graph 52, the three different nitrogen peaks 50 are each shifted far to the left of the interface 46 between the oxide of the gate oxide layer 32 and the silicon of the photodiode 30. In other words, the nitrogen peaks 50 are not directly beneath, or even generally vertically aligned with, the interface 46. Rather, the nitrogen peak in FIG. 4 is horizontally offset or spaced apart from the interface 46. This provides an improved level (i.e., reduced amount) of random noise, dark current, and/or leakage current in the CIS device 10.

While the disclosure provides illustrative embodiments, this description is not intended to be construed in a limiting sense. Various modifications and combinations of the illustrative embodiments, as well as other embodiments, will be apparent to persons skilled in the art upon reference to the description. It is therefore intended that the appended claims encompass any such modifications or embodiments.

What is claimed is:

1. A semiconductor device, comprising:
first and second isolation regions supported by a substrate;
a first array well supported by the first isolation region, the first array well having a first field implant layer embedded therein, the first field implant layer surrounding a first shallow trench isolation region;
a second array well supported by the second isolation region, the second array well supporting a doped region and a drain and having a second field implant layer embedded therein, the second field implant layer surrounding a second shallow trench isolation region;
a stack of photodiodes disposed in the substrate between the first and second isolation regions; and
a gate oxide formed over an uppermost photodiode of the stack of the photodiodes, the gate oxide and a silicon of the uppermost photodiode forming an interface, a nitrogen concentration at the interface offset from a peak nitrogen concentration.

2. The semiconductor device of claim 1, wherein the peak nitrogen concentration is disposed in the gate oxide.

3. The semiconductor device of claim 1, wherein the peak nitrogen concentration is offset from the nitrogen concentration at the interface by at least two nanometers.

4. The semiconductor device of claim 1, wherein the peak nitrogen concentration is offset from the nitrogen concentration at the interface by at least five nanometers.

5. The semiconductor device of claim 1, wherein a transfer transistor is formed over a central portion of the gate oxide.

6. The semiconductor device of claim 5, wherein a layer of polysilicon is formed over the transfer transistor.

7. The semiconductor device of claim 6, wherein a sidewall oxide is formed over the gate oxide outside the transfer transistor.

8. The semiconductor device of claim 7, wherein a remote plasma oxide is formed over the sidewall oxide.

9. The semiconductor device of claim 8, wherein a contact etch stop layer is formed over the remote plasma oxide and the layer of polysilicon.

10. The semiconductor device of claim 1, wherein the gate oxide is formed from two or more discrete layers of oxide.

11. The semiconductor device of claim 1, wherein the stack of photodiodes includes at least four vertically stacked photodiodes.

12. A semiconductor device, comprising:
first and second isolation regions supported by a substrate;
a first array p-well supported by the first isolation region, the first array p-well having a first p-type field implant layer embedded therein, the first p-type field implant layer surrounding a first shallow trench isolation region;
a second array p-well supported by the second isolation region, the second array p-well supporting an n-type doped region and a pixel n-type lightly doped drain and having a second p-type field implant layer embedded therein, the second p-type field implant layer surrounding a second shallow trench isolation region;
a stack of photodiodes disposed in the substrate between the first and second isolation regions; and
a gate oxide formed over an uppermost photodiode of the stack of the photodiodes, the gate oxide and a silicon of the uppermost photodiode forming an interface, a nitrogen concentration at the interface less than a peak nitrogen concentration.

13. The semiconductor device of claim 12, wherein the peak nitrogen concentration occurs in the gate oxide.

14. The semiconductor device of claim 12, wherein the peak nitrogen concentration is offset from the nitrogen concentration at the interface by at least two nanometers.

15. The semiconductor device of claim 12, wherein the peak nitrogen concentration is offset from the nitrogen concentration at the interface by at least five nanometers.

16. The semiconductor device of claim 12, wherein a transfer transistor is formed over a central portion of the gate oxide and a layer of polysilicon is formed over the transfer transistor.

17. The semiconductor device of claim 12, wherein the gate oxide is formed from two or more discrete layers of oxide.

18. A method of forming a semiconductor device, comprising:
forming first and second isolation regions over a substrate;
forming a first array p-well over the first isolation region, the first array p-well having a first p-type field implant layer embedded therein, the first p-type field implant layer surrounding a first shallow trench isolation region;
forming a second array p-well over the second isolation region, the second array p-well supporting an n-type doped region and a pixel n-type lightly doped drain and having a second p-type field implant layer embedded therein, the second p-type field implant layer surrounding a second shallow trench isolation region;
forming a stack of photodiodes in the substrate between the first and second isolation regions; and
forming a gate oxide formed over an uppermost photodiode of the stack of the photodiodes, the gate oxide and a silicon of the uppermost photodiode forming an interface, a nitrogen concentration at the interface offset from a peak nitrogen concentration.

19. The method of claim 18, further comprising shifting the peak nitrogen concentration into the gate oxide.

20. The method of claim 18, further comprising manipulating the peak nitrogen concentration by controlling at least one of a gas flow rate, a process time, and a concentration of nitrogen during formation of the gate oxide.
